(19) United States
(12) Patent Application Publication
(10) Pub. No.: US 2020/0371426 A1
(43) Pub. Date: Nov. 26, 2020

(54) ANTI-STATIC PHOTOMASK

(71) Applicant: Winbond Electronics Corp., Taichung City (TW)

(72) Inventors: Tsung-Wei LIN, Taichung City (TW); Chun-Yen LIAO, Taichung City (TW); Chun-Sheng WU, Taichung City (TW); Chen-Hsiang FANG, Taichung City (TW); Chung-Chen HSU, Taichung City (TW)

(21) Appl. No.: 16/419,340

(22) Filed: May 22, 2019

(51) Int. Cl. G03F 1/40; G03F 1/24

(52) U.S. Cl. CPC G03F 1/40; G03F 1/24

(57) ABSTRACT

The present invention relates to an anti-static photomask, including a substrate and a patterned mask layer formed on the substrate. The patterned mask layer includes a conductive strip and a conductive string, wherein the conductive strip includes an end, and the conductive string includes an isolated end. The end of the conductive strip is connected to the conductive string.

### BACKGROUND OF THE INVENTION

### Field of the Invention

The present invention relates to a photomask, and more particularly to an anti-static photomask.

### Description of the Related Art

The use of a photomask is necessary during lithography processes presently in use. However, static charge can accumulate on the photomask during use. If too much static charge is accumulated on the photomask, an electrostatic discharge may happen on the photomask pattern, which may damage the pattern after exposure. For example, the end of the photomask pattern which is adjacent to metal wiring will have a stronger electric field due to accumulation of a static charge in the current photomask. Problems such as cracking at corners of the photomask, damaging the pattern, Cr migration, haze, etc. have a higher chance of occurring in regions having a stronger electric field (e.g. the region corresponding to the static charge e indicated by the dashed line in FIG. 2C). As a result, unwanted patterns may be developed on the wafer, which can cause short circuits or circuits.

### BRIEF SUMMARY OF THE INVENTION

The present disclosure relates to an anti-static photomask, including a substrate and a patterned mask layer formed on the substrate. The patterned mask layer includes a conductive strip and a conductive string, wherein the conductive strip includes an end, and the conductive string includes an isolated end. The end of the conductive strip is connected to the conductive string.

In the anti-static photomask in some embodiments of the present disclosure, the conductive string further includes a connecting end and the conductive string is connected to the end of the conductive strip through the connecting end. The width of the isolated end is greater than the width of the connecting end. In other embodiments, the conductive string further includes another isolated end. The patterned mask layer further includes another conductive strip, including an end connected to the conductive string. The conductive string further includes another isolated end.

In some embodiments, the patterned mask layer further includes another connecting string, including an isolated end and a connecting end, wherein the connecting end of another connecting string is connected to the end of the conductive strip. The width of the conductive strip is greater than two times the width of the conductive string. The patterned mask layer further includes another conductive string, and the two conductive strings are parallel and separated from each other by a distance.

### BRIEF DESCRIPTION OF THE DRAWINGS

Aspects of this disclosure are best understood from the following detailed description when read with the accompanying figures. It should be noted that, in accordance with common practice in the industry, various features are not drawn to scale. In fact, the dimensions of the various features may be arbitrarily increased or reduced for clarity of discussion.

FIG. 1 is a schematic view of a photomask according to some embodiments of the present disclosure.

FIGS. 2A to 2B are schematic views of patterned mask layers and their corresponding pattern in some embodiments of the present disclosure.

FIG. 2C is a schematic view of patterned mask layer and its corresponding pattern in some embodiments of the present disclosure.

FIGS. 3A to 3B are schematic views of patterned mask layers and their corresponding pattern in some embodiments of the present disclosure.

FIGS. 4A to 4B are schematic views of patterned mask layers and their corresponding pattern in some embodiments of the present disclosure.

FIG. 4C is a schematic view of patterned mask layer and its corresponding pattern in some embodiments of the present disclosure.

FIGS. 5 to 7 are schematic views showing the charge distribution when using different patterned mask layers to form patterns.

### DETAILED DESCRIPTION OF THE INVENTION

The following disclosure provides many different embodiments, or examples, for implementing different features of the subject matter provided. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

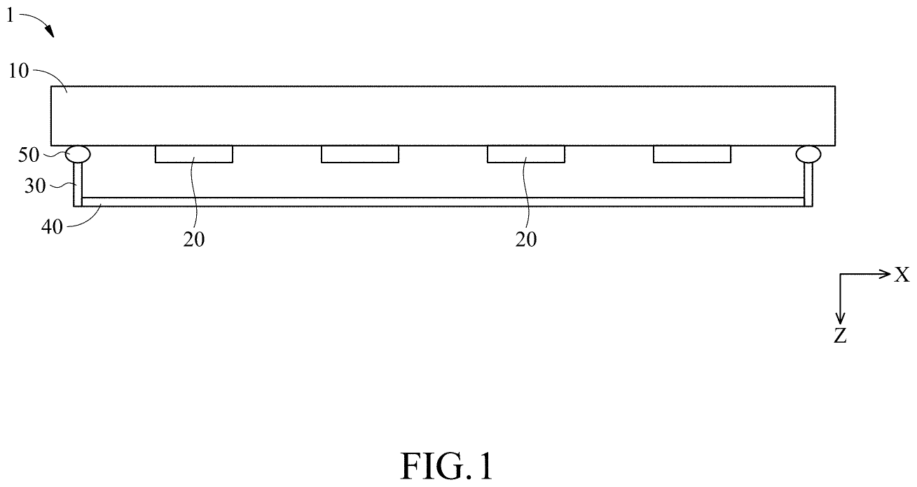

FIG. 1 is a schematic view of a photomask 1 (anti-static photomask) in some embodiments of the present disclosure. The photomask 1 includes a substrate 10, a patterned mask layer 20 formed on the substrate 10, a frame 30, a thin film 40, and a connecting material 50 connecting the substrate 10 and the frame 30. The substrate 10 may be any suitable substrate for a photomask. The patterned mask layer 20 and the frame 30 may be formed from metal (such as MoSi, Cr, etc.), and may be formed on the substrate 10 by suitable processes. The thin film 40 is used to prevent dust from entering the photomask 1, so as to protect other elements (such as the substrate 10, the patterned mask layer 20 and the frame 30). The connecting material 50 is used to connect the substrate 10 and the frame 30 and may include various suitable adhesives.

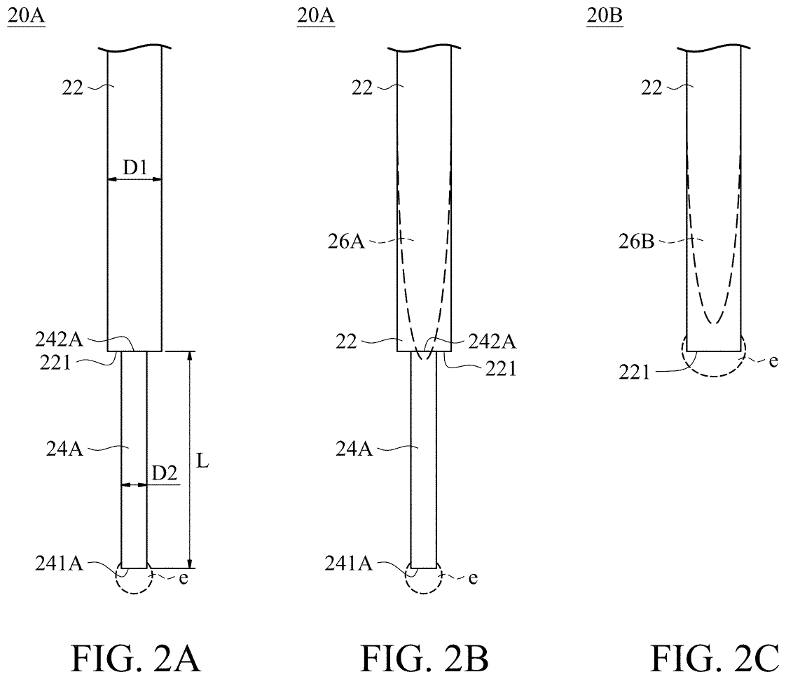

FIG. 2A is a top view of a portion of the patterned mask layer 20A in some embodiments of the present disclosure. In FIG. 2A, the patterned mask layer 20A mainly includes a conductive strip 22 and a conductive string 24A formed from an identical material or similar materials. The conductive strip 22 is a portion of the main pattern of the photomask 1, and the conductive strip 22 includes an end 221 electrically connected to a connecting end 242A of the conductive string 24A. Another end of the conductive string 24A is called isolated end 241A.

It should be noted that the term “isolated end” herein means an end which is not physically connected to other conductive structures (such as the conductive strip 22, the frame 30 or other conductive structures). Furthermore, although the conductive strip 22 and the conductive string 24A are shown separately, they may be formed in a same process.

In this embodiment, the dimensions of the conductive strip 22 and the conductive string 24A are relative to the wavelength (λ) of the light source and the numerical aperture (NA) during patterning. For example, the width D2 of the conductive string 24A may be designed to be less than λ/NA (i.e. D2<λ/NA), and the width D1 of the conductive strip 22 may be designed to be greater than two times the width D2 of the conductive string 24A (D1>2*D2). As a result, the pattern will form on the photoresist in a position that corresponds to the wider conductive strip 22 rather than to the narrower conductive string 24A. In other words, the conductive string 24A is an assist feature which does not form any pattern. Furthermore, the length L of the conductive string 24A may be designed to be greater than two times the width D2 (L≥2*D2) to achieve better patterning results.

Furthermore, the static charge e of the patterned mask layer 20A may be guided to the isolated end 241A of the conductive string 24A, which does not form a pattern, by providing electrical connection between the end 221 of the conductive strip 22 and the conductive string 24A, so as to prevent problems such as cracking at corners of the photomask, damaging the pattern, Cr migration, haze and so on, which can occur at the ends of the main pattern (i.e. the end 221 of the conductive strip 22), so the influence that the static charge e has on the pattern on the photomask after exposure may be reduced. In other words, no pattern will form on the photoresist in the position corresponding to the conductive string 24A because the width of the conductive string 24A is too low to form an image even if the static charge e is accumulated on the isolated end 241A of the conductive string 24A and causes electrostatic discharge. As a result, the corresponding pattern on the photoresist will not be damaged by the electrostatic discharge.

For example, FIGS. 2B and 2C are schematic views of a portion of the patterned mask layer 20A and a patterned mask layer 20B in another embodiment and their corresponding patterns, wherein a corresponding pattern 26A and a pattern 26B may be formed by the patterned mask layer 20A and the patterned mask layer 20B, respectively. It should be noted that the static charge e is accumulated on the isolated end 241A and the end 221 in FIGS. 2B and 2C, respectively. In other words, the static charge e accumulated on the end 221 (FIG. 2C) may be guided to the isolated end 241A (FIG. 2B) which does not form a pattern by providing the conductive string 24A at the end of the conductive strip 22. As a result, even if problems such as cracking at corners of the photomask, damaging the pattern, Cr migration, haze, etc. occur at the isolated end 241A due to electrostatic discharge at the isolated end 241A, which itself was due to the accumulation of the static charge e, no corresponding pattern will form during exposure because no pattern will form corresponding to the conductive string 24A. Unwanted patterns may be prevented from forming on the photoresist in the position corresponding to the ends of the main pattern due to electrostatic discharge (such as to prevent pattern damage during exposure at the end 221 of the patterned mask layer 20B, which is the position of the static charge e performing electrostatic discharge). Moreover, the yield of the lithography process may be increased by using the photomask 1. Furthermore, the lifetime of the photomask 1 may be extended, so the cost may be reduced. Moreover, the conductive string 24A is connected to the end 221 of the conductive strip 22 rather than in other positions, so the width of the pattern formed by the photomask 1 will not be interfered with. Furthermore, the conductive string 24A has the function of resolution assisting, so the shape of the pattern 26A may be more similar to the conductive strip 22 (original image) than the pattern 26B does.

It should be noted that although the conductive strip 22 and the conductive string 24A are illustrated as extending in directions that are substantially identical, the present disclosure is not limited thereto. For example, in some embodiments, an angle θ between the conductive strip 22 and the conductive string may be smaller than 180 degrees. In other embodiments, the conductive strip 22 may be formed on the XY plane (i.e. a plane parallel to the substrate 10), and the conductive string may extend to any direction that is not on the XY plane (e.g. along the Z direction, which is perpendicular to the substrate 10). This configuration also allows the static charge e being guided to the isolated end of the conductive string, so the damage caused by electrostatic discharge to the photomask 1 and its corresponding pattern may be prevented, and the design flexibility may be increased, too.

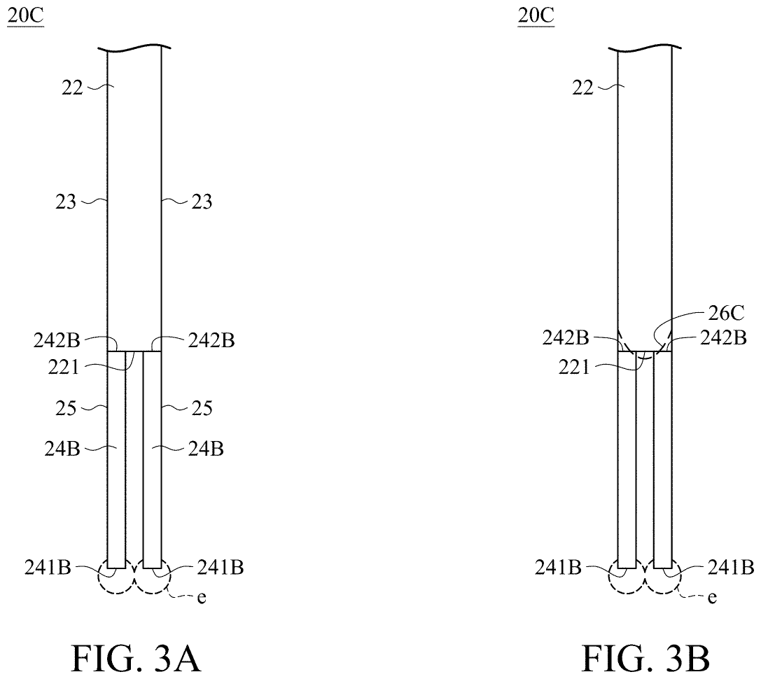

FIGS. 3A and 3B are schematic views of a patterned mask layer 20C in some embodiments of the present disclosure. In this embodiment, the end 221 of one conductive strip 22 is connected to two connecting ends 242 of two conductive strings 24B. In other words, one conductive strip 22 may correspond to two conductive strings 24B, but the present disclosure is not limited thereto. One conductive strip 22 may correspond to more than two conductive strings 24B as long as the design is compatible. In this embodiment, the static charge e may also be guided to the isolated ends 241B of the conductive strings 24B to prevent damage to the photomask 1 and its corresponding pattern caused by electrostatic discharge.

It is worth noted that the shape of the corresponding pattern 26C may be more similar to the shape of the conductive strip by connecting the end 221 of a single conductive strip 22 to a plurality of connecting ends of conductive strings, so the distortion of the corresponding patterns may be further prevented (such as reducing the occurrence of rounded corners on the corresponding pattern), especially compared to the embodiments of FIG. 2B or 2C. In some embodiments, as shown in FIG. 3A, both sides 25 of the two connecting strings 24B connected to a single conductive strip 22 are tangential to the sides 23 of the conductive strip 22.

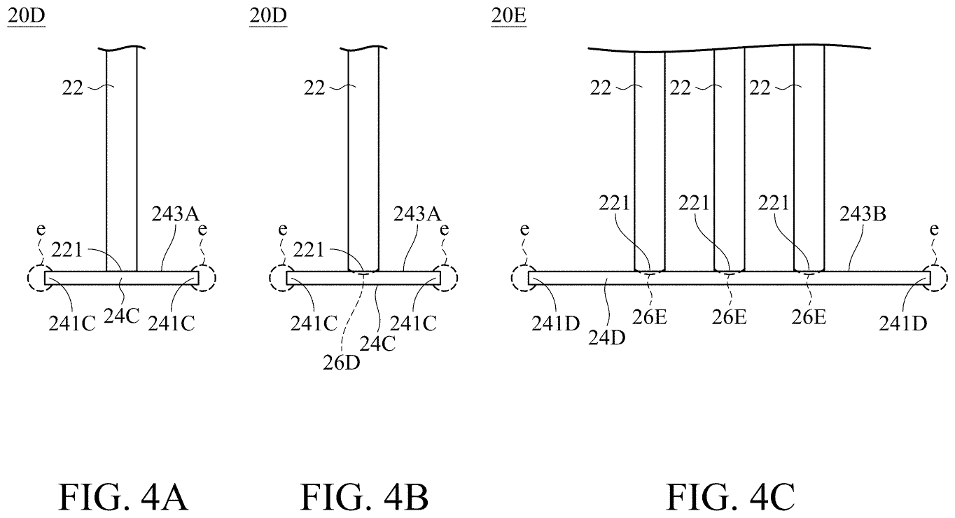

FIGS. 4A to 4C are schematic views of patterned mask layers 20D and 20E in some embodiments of the present disclosure. In FIGS. 4A and 4B, the conductive string 24C is connected to the end 221 of the conductive strip 22 by a side 243A rather than by the connecting end as in previous embodiments. Furthermore, the conductive string 24C also has isolated ends 241C. In this embodiment, the static charge e may also be guided to the two isolated ends 241C to prevent damage caused by electrostatic discharge to the photomask 1 and its corresponding pattern. Furthermore, in this embodiment, the shape of the corresponding pattern 26D may be formed in such a way that it is similar to the shape of the conductive strip 22 by connecting the end of the conductive strip 22 to the side 243A of the conductive string 24C, so the distortion of the corresponding patterns may be further prevented (such as reducing the occurrence of rounded corners on the corresponding pattern), especially compared to the embodiments of FIG. 2B or 2C.

The conductive string is not connected to the conductive strip 22 by its end in this embodiment, so a plurality of conductive strips 22 may be connected to one conductive string. For example, referring to FIG. 4C, the conductive string 24D of the patterned mask layer 20E may be connected to the ends 221 of more than one conductive strip 22 (three conductive strips 22 are shown in FIG. 4C, but the present disclosure is not limited thereto), and the conductive string 24D also has isolated ends 241D. In this embodiment, static charge e on a plurality of conductive strips 22 may also be guided to the two isolated ends 241D of the conductive string 24D to prevent damage to the photomask 1 and its corresponding pattern caused from electrostatic discharge. Furthermore, the conductive string 24D can connect a plurality of conductive strips 22 in series to reduce the potential difference between the conductive strips and the accumulation of the static charge to reach a result like grounding.

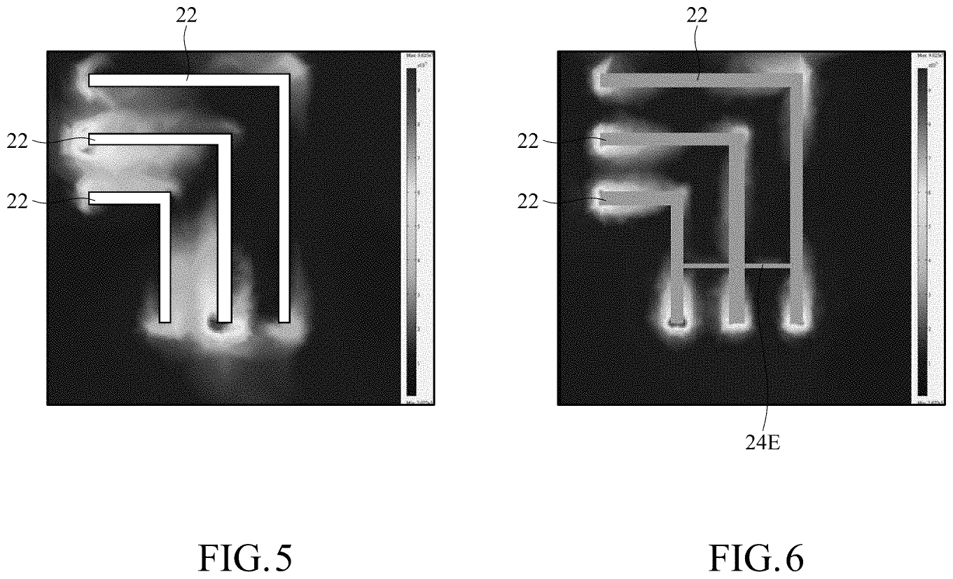

FIGS. 5 to 7 are schematic views showing the charge distribution when using different patterned mask layers to form patterns, wherein different colors of the positions adjacent to the conductive strips 22 represent different density of static charge. In FIG. 5, no conductive string that does not form pattern is provided, and the conductive strips 22 are separated from each other by a certain distance. In this situation, the ends of the conductive strips 22 may have higher charge density. Furthermore, the conductive strips 22 are not electrically connected to each other, so potential difference will occur at the conductive strips 22 and causes the charge density of the conductive strips 22 to be uneven. As a result, problems such as electrostatic discharge and pattern distortion will occur.

In FIG. 6, the conductive strips 22 are connected to each other by a conductive string 24E. As a result, the conductive strips 22 may be electrically connected to each other to make the conductive strips 22 have an identical potential, and the static charge may be separated. However, the conductive string 24E is not connected to the ends of the conductive strips 22, so the problem of static charge accumulation at the ends of the main pattern (such as the conductive strips 22) cannot be solved. Therefore, electrostatic discharge and pattern distortion may still occur in these positions.

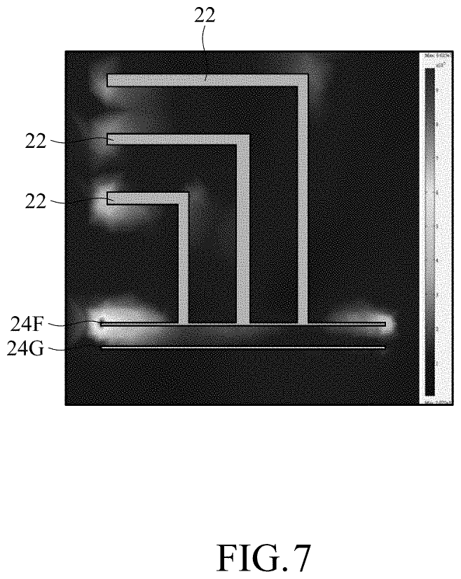

In some embodiments of the present disclosure, the ends of the conductive strips 22 of this patterned mask layer are connected to each other by a conductive string 24F in FIG. 7. As a result, compared to the conditions illustrated in FIG. 5, static charge may be separated by a conductive string 24F that provides an electrical connection to the conductive strips 22, and the potential difference and static charge accumulation of the conductive strips 22 may be reduced to achieve a result like grounding. Compared to the conditions illustrated in FIG. 6, damage caused by electrostatic discharge at the ends of the conductive strips 22 may be prevented because the conductive string 24F is disposed at the ends of the conductive strips 22 to further guide the static charge to the ends of the conductive string 24F that does not form any patterns. As a result, damage to the corresponding pattern of the conductive strips 22 and to the photomask 1 may be prevented.

Furthermore, in FIG. 7, the electric field of the patterned mask may be changed by providing another conductive string 24G, so the shape of the pattern formed by the photomask 1 may be further enhanced for a better resolution.

One end of the conductive string is an isolated end which is not connected to other conductive structures (such as the conductive strip 22 or the frame 30), so the conductive strip does not have to be connected to the frame 30 in the present disclosure. As a result, the frame 30 may be omitted in some embodiments to further decrease the cost of the photomask 1.

In summary, the present disclosure provides a photomask having a patterned mask layer with an additional conductive string which does not form any patterns and is electrically connected to the main pattern (such as conductive strip), wherein the conductive string includes an isolated end which is not electrically connected to other conductive structure. The problem of pattern damage due to static charge accumulation at the ends of the main pattern may be prevented by this conductive string. Furthermore, the corresponding pattern formed by the photomask may be similar to the desired pattern.

The foregoing outlines features of several embodiments so that those skilled in the art may better understand the aspects of the present disclosure. Those skilled in the art should also realize that such equivalent constructions do not depart from the spirit and scope of the present disclosure, and that they may make various changes, substitutions, and alterations herein without departing from the spirit and scope of the present disclosure. Furthermore, each claim constitutes its embodiment, and the scope of the present disclosure also covers the combination of the claims and embodiments.

What is claimed is:

1. An anti-static photomask, comprising:
a substrate;
a patterned mask layer formed on the substrate, comprising:
a conductive strip comprising an end; and
a conductive string comprising an isolated end, wherein the end of the conductive strip is connected to the conductive string.

2. The anti-static photomask as claimed in claim 1, wherein the conductive string further comprises a connecting end, and the conductive string is connected to the end of the conductive strip through the connecting end.

3. The anti-static photomask as claimed in claim 2, wherein a width of the isolated end is greater than a width of the connecting end.

4. The anti-static photomask as claimed in claim 1, wherein the conductive string further comprises another isolated end.

5. The anti-static photomask as claimed in claim 1, wherein the patterned mask layer further comprises another conductive strip, comprising an end connected to the conductive string.

6. The anti-static photomask as claimed in claim 5, wherein the conductive string further comprises another isolated end.

7. The anti-static photomask as claimed in claim 1, wherein the patterned mask layer further comprises another connecting string, comprising an isolated end and a connecting end, the connecting end of another connecting string is connected to the end of the conductive strip.

8. The anti-static photomask as claimed in claim 1, wherein a width of the conductive strip is greater than a width of the conductive string.

9. The anti-static photomask as claimed in claim 8, wherein the width of the conductive strip is greater than two times the width of the conductive string.

10. The anti-static photomask as claimed in claim 1, wherein the patterned mask layer further comprises another conductive string, and the two conductive strings are parallel and separated from each other by a distance.
